(19) United States
(12) Patent Application Publication
(10) Pub. No.: US 2026/0123516 A1
(43) Pub. Date: Apr. 30, 2026

(54) Method for Fabrication of Bonded Chiplets and Related Structure

(71) Applicant: Newport Fab, LLC dba Tower Semiconductor Newport Beach, Newport Beach, CA (US)

(72) Inventors: Michael Lee, Los Angeles, CA (US); Oleg Martynov, Lebanon, NH (US); David J. Howard, Irvine, CA (US)

(21) Appl. No.: 18/933,015

(22) Filed: Oct. 31, 2024

(51) Int. Cl. H01L 23/31; H01L 21/311; H01L 21/762; H01L 23/48; H01L 23/498; H01L 25/16; H01L 33/30

(52) U.S. Cl. CPC H10W 74/114; H10H 20/824; H10P 50/283; H10P 90/1908; H10W 10/061; H10W 10/181; H10W 90/00; H10W 20/20; H10W 70/635

(57) ABSTRACT

In fabricating a semiconductor structure, a substrate is provided. A chiplet is bonded to the substrate. The chiplet includes a bulk layer and an active layer. A first blanket dielectric is formed over the chiplet and the substrate. A first portion of the first blanket dielectric over the chiplet is thinned. The first blanket dielectric is etched to expose the bulk layer without exposing the active layer. The bulk layer is removed. A second blanket dielectric is formed over the active layer and the first blanket dielectric. A second portion of the second blanket dielectric over the active layer is planarized with the first blanket dielectric. A first device is formed from the active layer.

### BACKGROUND

Optoelectronic devices are commonly utilized in data communications. Various applications of optoelectronic devices can utilize an electro-optical effect to affect changes in optical properties (such as phase, amplitude, wavelength, polarization, etc.).

Certain materials, such as group III-V compound semiconductors or Pockels material, have characteristics that make them advantageous for use in optoelectronic devices.

However, operations that are incidental to and supportive of these optoelectronic devices, such as input/output coupling, feedback, and modulation, may be more easily implemented using a different type of material, such as group IV semiconductors, such as silicon.

In one approach, dies of a first material type are heterogeneously integrated on substrates of a second material type. Carrier or bulk layers are used for handling the dies during integration, and then the bulk layers are removed, leaving active layers of the dies, which can be fashioned into optoelectronic devices. However, conventional techniques for removing bulk layers tend to leave residual structures that require complex design considerations. More actions are often needed to completely remove bulk layers, increasing fabrication time and cost. Further, forming optoelectronic devices with predetermined dimensions can require starting with larger dies in order to account for the volumes of bulk layers that will become residual structure, thereby leaving less area for integrating other elements.

Conventional techniques can also fail to properly protect active layers during removal of bulk layers, due to poor encapsulation of the active layers and/or due to the protective layers notwithstanding the harsh additional actions needed to completely remove the bulk layers. Damage to active layers negatively impacts the performance of optoelectronic devices formed therefrom. Moreover, integrated structures can also have significant layer contouring between areas overlying an optoelectronic device and areas overlying adjacent elements. Processing such non-planar topologies can require specialized fabrication technologies, and can make lithography and alignment difficult such that smaller devices are more prone to fabrication errors.

Thus, there is need in the art to more efficiently and effectively integrate heterogenous structures with improved performance and reduced complexity.

### SUMMARY

The present disclosure is directed to methods for fabrication of bonded chiplets and related structures substantially as shown in and/or described in connection with at least one of the figures, and as set forth in the claims.

### BRIEF DESCRIPTION OF THE DRAWINGS

FIG. 1A illustrates a portion of a flowchart of an exemplary method for manufacturing a semiconductor structure according to one implementation of the present application.

FIG. 1B illustrates a portion of a flowchart of an exemplary method for manufacturing a semiconductor structure, as a continuation to the flowchart of FIG. 1A, according to one implementation of the present application.

FIG. 2A illustrates a layout of a semiconductor structure processed in accordance with the flowchart of FIG. 1A according to one implementation of the present application.

FIG. 2B illustrates a cross-sectional view of a portion of a semiconductor structure corresponding to FIG. 2A processed in accordance with the flowchart of FIG. 1A according to one implementation of the present application.

FIG. 3 illustrates a cross-sectional view of a portion of a semiconductor structure processed in accordance with the flowchart of FIG. 1A according to one implementation of the present application.

FIG. 4A illustrates a layout of a semiconductor structure processed in accordance with the flowchart of FIG. 1A according to one implementation of the present application.

FIG. 4B illustrates a cross-sectional view of a portion of a semiconductor structure corresponding to FIG. 4A processed in accordance with the flowchart of FIG. 1A according to one implementation of the present application.

FIG. 5 illustrates a cross-sectional view of a portion of a semiconductor structure processed in accordance with the flowchart of FIG. 1A according to one implementation of the present application.

FIG. 6 illustrates a cross-sectional view of a portion of a semiconductor structure processed in accordance with the flowchart of FIG. 1A according to one implementation of the present application.

FIG. 7 illustrates a cross-sectional view of a portion of a semiconductor structure processed in accordance with the flowchart of FIG. 1B according to one implementation of the present application.

FIG. 8 illustrates a cross-sectional view of a portion of a semiconductor structure processed in accordance with the flowchart of FIG. 1B according to one implementation of the present application.

FIG. 9 illustrates a cross-sectional view of a portion of a semiconductor structure processed in accordance with the flowchart of FIG. 1B according to one implementation of the present application.

FIG. 10 illustrates a cross-sectional view of a portion of a semiconductor structure processed in accordance with the flowchart of FIG. 1B according to one implementation of the present application.

FIG. 11 illustrates a cross-sectional view of a portion of a semiconductor structure processed in accordance with the flowchart of FIG. 1B according to one implementation of the present application.

FIG. 12 illustrates a cross-sectional view of a portion of a semiconductor structure processed in accordance with the flowchart of FIG. 1B according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions. As used herein, “over” may refer to directly or indirectly over.

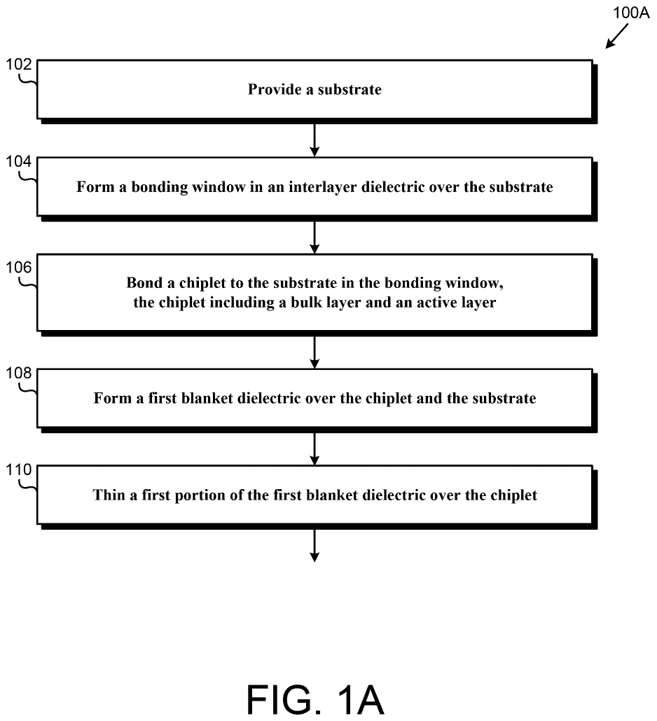

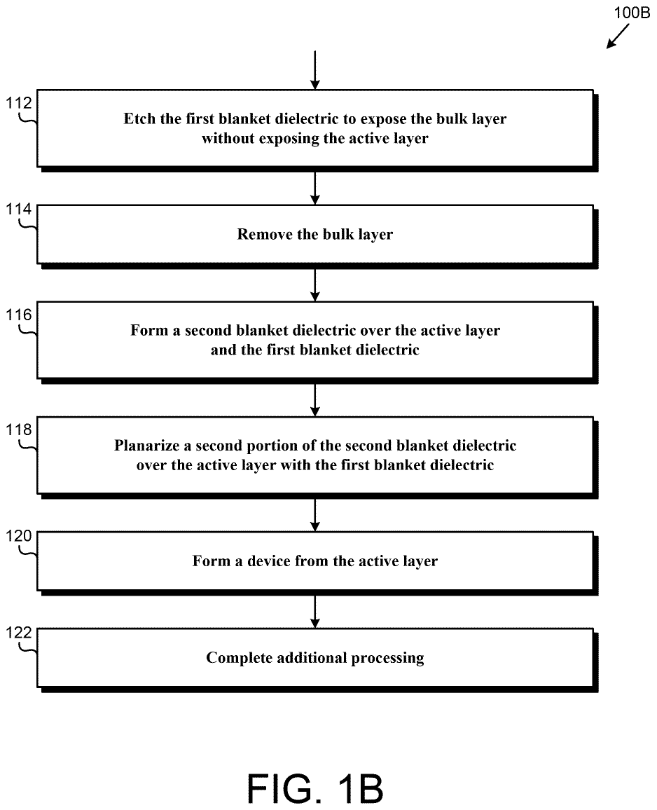

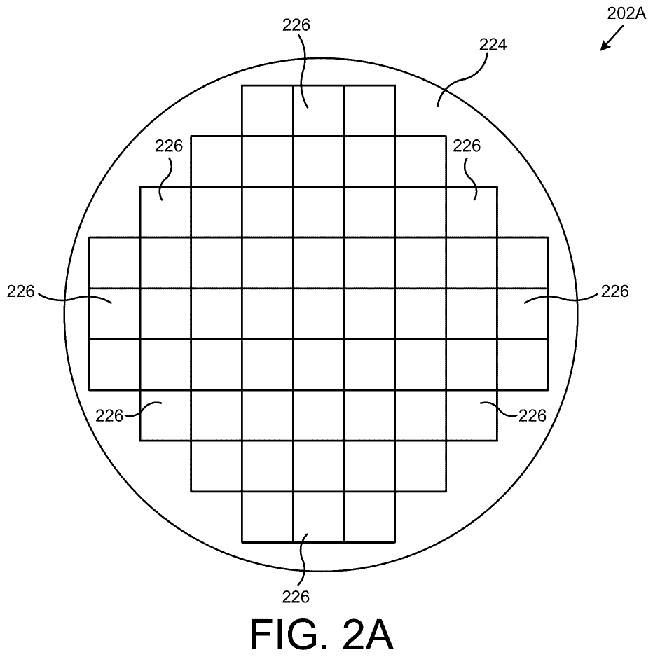

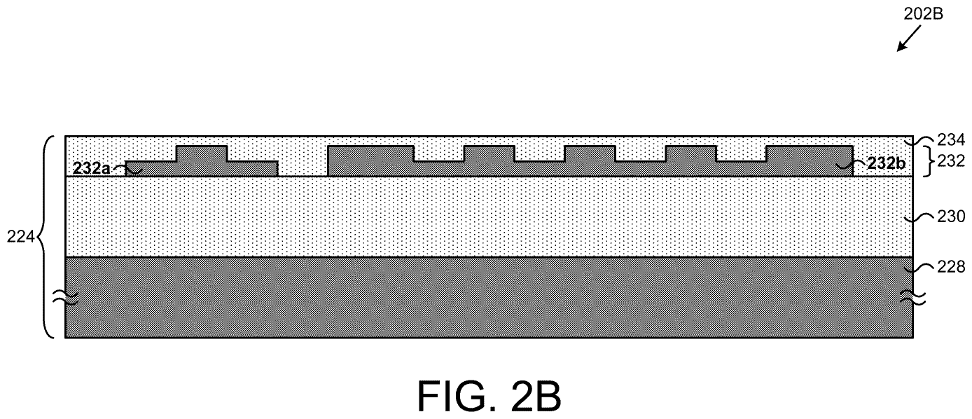

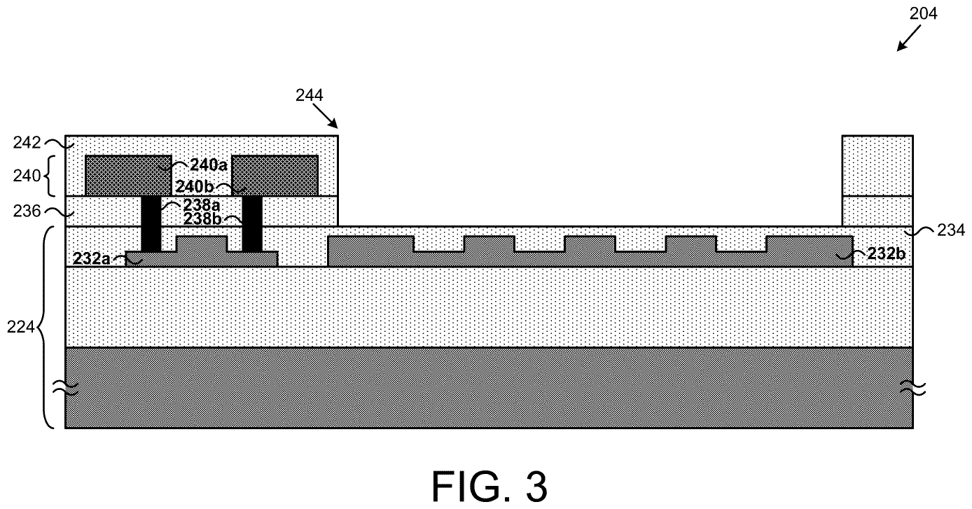

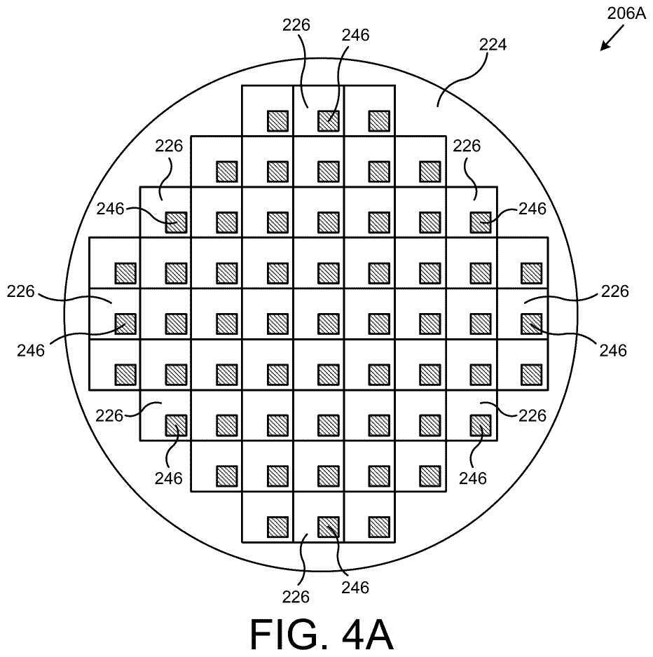

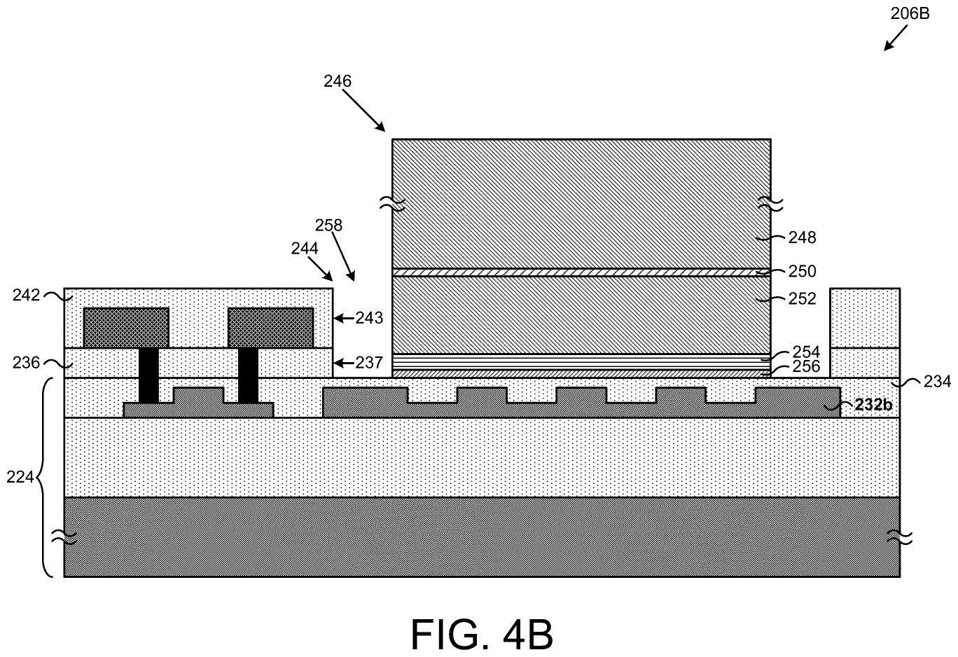

FIG. 1A illustrates a portion of a flowchart of an exemplary method for manufacturing a semiconductor structure according to one implementation of the present application. Structures shown in FIGS. 2A through 6 illustrate the results of performing actions 102 through 110 shown in flowchart 100 of FIG. 1A. For example, FIG. 2A shows a semiconductor structure after performing action 102 in FIG. 1A, FIG. 3 shows a semiconductor structure after performing action 104 in FIG. 1A, FIG. 4A shows a semiconductor structure after performing action 106 in FIG. 1A, and so forth.

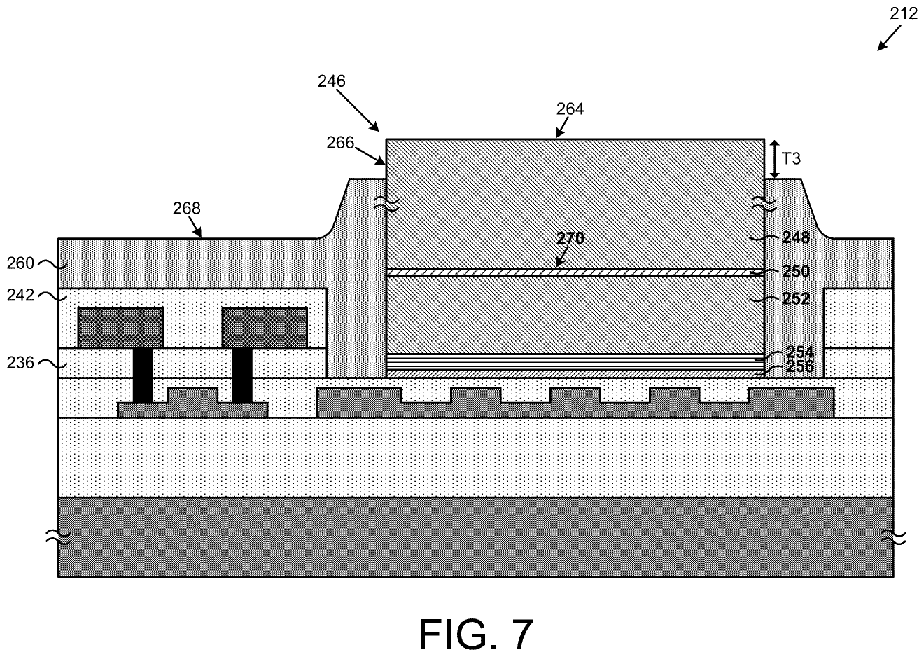

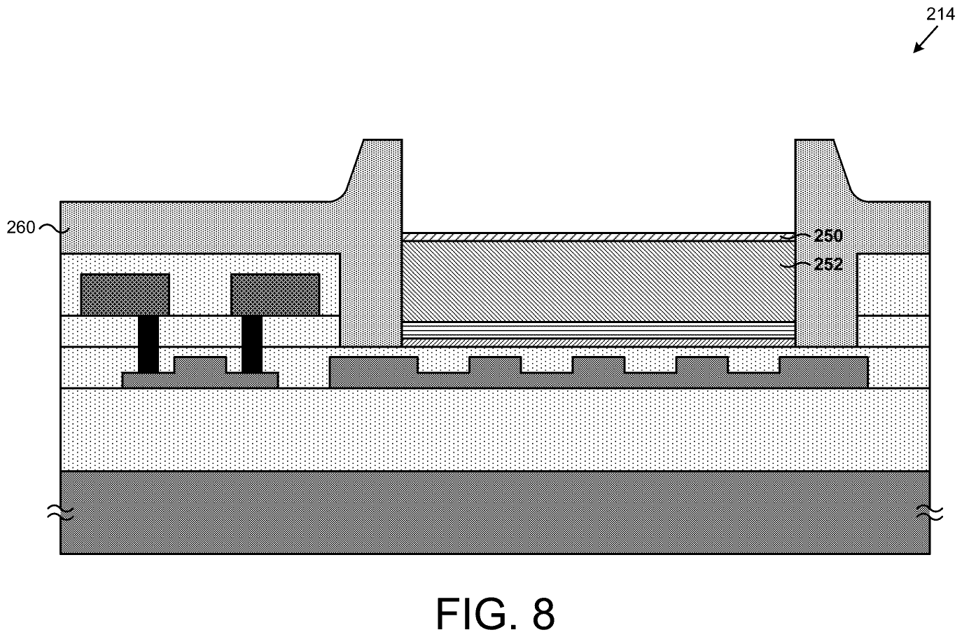

FIG. 1B illustrates a portion of a flowchart of an exemplary method for manufacturing a semiconductor structure, as a continuation to flowchart 100 of FIG. 1A, according to one implementation of the present application. Structures shown in FIGS. 7 through 12 illustrate the results of performing actions 112 through 122 shown in flowchart 100B of FIG. 1B. For example, FIG. 7 shows a semiconductor structure after performing action 112 in FIG. 1B, FIG. 8 shows a semiconductor structure after performing action 114 in FIG. 1B, and so forth.

Actions 102 through 122 shown in flowcharts 100A and 100B of FIGS. 1A and 1B are sufficient to describe one implementation of the present inventive concepts. Other implementations of the present inventive concepts may utilize actions different from those shown in flowcharts 100A and 100B of FIGS. 1A and 1B. Certain details and features have been left out of the flowcharts that are apparent to a person of ordinary skill in the art. For example, an action may consist of one or more sub-actions or may involve specialized equipment or materials, as known in the art. Moreover, some actions, such as masking and cleaning actions, may be omitted so as not to distract from the illustrated actions.

FIG. 2A illustrates a layout of a semiconductor structure processed in accordance with action 102 in flowchart 100A of FIG. 1A according to one implementation of the present application. As shown in FIG. 2A, in semiconductor structure 202A, substrate 224 is provided.

Substrate 224 includes multiple integrated circuits (ICs) 226. In one implementation, substrate 224 is a group IV substrate. As used herein, the phrase “group IV” refers to a semiconductor material that includes at least one group IV element such as silicon (Si), germanium (Ge), and carbon (C), and may also include compound semiconductors such as silicon germanium (SiGe) and silicon carbide (SiC), for example. “Group IV” also refers to semiconductor materials that include more than one layer of group IV elements, or doping of group IV elements to produce strained group IV materials, and may also include group IV based composite substrates such as silicon on insulator substrates, separation by implantation of oxygen (SIMOX) process substrates, and silicon on sapphire (SOS) substrates, for example. In one implementation, substrate 224 is a semiconductor-on-insulator (SOI) wafer having a diameter of approximately two hundred millimeters (200 mm). In various implementations, substrate 224 can be glass, quartz, or sapphire.

In various implementations, substrate 224 can include greater or fewer ICs 226 than those shown in FIG. 2A. In the present implementation, ICs 226 have an approximately square shape. In one implementation, each of ICs 226 has dimensions of approximately twenty microns by approximately twenty microns (20 μm×20 μm). In various implementations, ICs 226 can have any other shapes and/or arrangements in substrate 224. As described below, each of ICs 226 can include devices, such as group IV devices (not shown in FIG. 2A).

FIG. 2B illustrates a cross-sectional view of a portion of a semiconductor structure corresponding to FIG. 2A processed in accordance with action 102 in the flowchart of FIG. 1A according to one implementation of the present application. The cross-sectional view in FIG. 2B generally corresponds to a portion of one of ICs 226 in FIG. 2A. As shown in FIG. 2B, in semiconductor structure 202B, substrate 224 is provided.

Semiconductor structure 202B includes substrate 224 having handle wafer 228, buried oxide (BOX) 230, semiconductor layer 232, and dielectric 234. In the present implementation, substrate 224 is a semiconductor-on-insulator (SOI) substrate. In providing substrate 224, a bonded and etch back SOI (BESOI) process can be used, as known in the art. Alternatively, as also known in the art, a SIMOX process or a “smart cut” process can also be used for providing substrate 224. In various implementations, substrate 224 may be another type of substrate other than an SOI substrate.

In one implementation, handle wafer 228 is undoped bulk silicon. In various implementations, handle wafer 228 can comprise germanium, group III-V material, or any other suitable handle material. In various implementations, handle wafer 228 has a thickness of approximately seven hundred microns (700 μm) or greater or less. In one implementation, a trap rich layer can be situated between handle wafer 228 and BOX 230. In various implementations, BOX 230 typically comprises silicon dioxide (SiO₂), but it may also comprise silicon nitride (Si_{X}N_{Y}), or another insulator material. In various implementations, BOX 230 has a thickness of approximately one micron (1 μm) to approximately three microns (3 μm) or greater or less. In one implementation, semiconductor layer 232 includes monocrystalline silicon. In various implementations, semiconductor layer 232 can comprise germanium, group III-V material, or any other semiconductor material. In various implementations, semiconductor layer 232 has a thickness of approximately three hundred nanometers (200 nm) to approximately five hundred nanometers (500 nm) or greater or less.

Semiconductor layer 232 includes devices 232a and 232b. Devices 232a and 232b can be any photonics or optoelectronics devices configured to generate, receive, transmit, or modify light. In various implementations, devices 232a and 232b can include a waveguide, a modulator, a grating coupler, an interferometer, a photodiode, or a phototransistor. For example, device 232a can be a modulator, and device 232b can be a grating coupler. Devices 232a and 232b can be formed, for example, by patterning, doping, and/or performing other processing on semiconductor layer 232 of substrate 224. In various implementations, semiconductor layer 232 can include other devices (not shown in FIG. 2B), such as a transistor, an operational amplifier, a driver, a filter, a mixer, or a diode.

Dielectric 234 is situated over semiconductor layer 232 and BOX 230. Dielectric 234 insulates devices 232a and 232b, and aids subsequent processing. In various implementations, dielectric 234 can comprise borophosphosilicate glass (BPSG), tetra-ethyl ortho-silicate (TEOS), SiO₂, Si_{X}N_{Y}, silicon oxynitride (Si_{X}O_{Y}N_{Z}), or another dielectric. Dielectric 234 can be formed by depositing and planarizing a dielectric layer.

FIG. 3 illustrates a cross-sectional view of a portion of a semiconductor structure processed in accordance with action 104 in flowchart 100A of FIG. 1A according to one implementation of the present application. As shown in FIG. 3, in semiconductor structure 204, bonding window 244 is formed in interlayer dielectrics 236 and 242 over substrate 224.

Semiconductor structure 204 includes interlayer dielectric 236, contacts 238a and 238b, interconnect metal layer 240 having interconnect metal segments 240a and 240b, interlayer dielectric 242, and bonding window 244. Interlayer dielectric 236 is formed over substrate 224. Interlayer dielectric 236 separates semiconductor layer 232 from interconnect metal layer 240. In various implementations, interlayer dielectric 236 can comprise SiO₂, Si_{X}N_{Y}, or Si_{X}O_{Y}N_{Z}. Interlayer dielectric 236 can be formed in a similar manner to dielectric 234, as described above. Although interlayer dielectric 236 is illustrated as a single dielectric layer in FIG. 3, an interlayer dielectric can be a combination of multiple dielectric layers.

Contacts 238a and 238b are situated in interlayer dielectric 236 and dielectric 234. Contacts 238a and 238b connect device 232a in semiconductor layer 232 to interconnect metal segments 240a and 240b, respectively, in interconnect metal layer 240. In one implementation, contact holes are etched in interlayer dielectric 236 and dielectric 234 over device 232a, a metal is deposited in the contact holes, and then the metal is planarized with interlayer dielectric 236, for example, using chemical mechanical polishing (CMP), thereby forming contacts 234a and 234b. In an alternative implementation, a damascene process is used to form contacts 238a and 238b. In various implementations, contacts 238a and 238b can comprise tungsten (W), copper (Cu), or aluminum (Al). In various implementations, a metal liner can be situated between contacts 238a and 238b and device 232a.

Interconnect metal layer 240 is provided over interlayer dielectric 236. Interconnect metal layer 240 includes interconnect metal segments 240a and 240b electrically coupled to contacts 238a and 238b respectively. In one implementation, a metal layer is deposited over interlayer dielectric 236 and contacts 238a and 238b, and then segments thereof are etched, thereby forming interconnect metal segments 240a and 240b. In an alternative implementation, a damascene process is used to form interconnect metal segments 240a and 240b. In various implementations, interconnect metal segments 240a and 240b can comprise W, Al, or Cu.

Contacts 238a and 238b and interconnect metal segments 240a and 240b together route electricity to/from device 232a, which can be, for example, a silicon Mach-Zehnder modulator. Although contacts 238a and 238b and interconnect metal segments 240a and 240b are illustrated as separate formations in FIG. 3, in other implementations they may be parts of the same formation. Semiconductor structure 204 can include other contacts and other interconnect metal segments not shown in FIG. 3. Interconnect metal segments 240a and 240b are situated in and under interlayer dielectric 242. Interlayer dielectric 242 can be formed in a similar manner to interlayer dielectric 236, as described above.

As shown in FIG. 3, bonding window 244 is formed in interlayer dielectrics 236 and 242. Bonding window 244 can be formed by patterning a lithographic mask on interlayer dielectric 242 to have an opening overlying device 232b, then etching through interlayer dielectrics 236 and 242 to dielectric 234 using, for example, reactive ion etching (RIE). In one implementation, a sacrificial etch stop (not shown) over dielectric 234 prevents etching of dielectric 234 and/or semiconductor layer 232. In such implementation, the sacrificial etch stop can be removed using a wet etch that is selective to the material of the sacrificial etch stop, such as a phosphoric acid wet etch selective to Si_{X}N_{Y}.

FIG. 4A illustrates a layout of a semiconductor structure processed in accordance with action 106 in flowchart 100A of FIG. 1A according to one implementation of the present application. As shown in FIG. 4A, in semiconductor structure 206A, chiplets 246 are bonded to substrate 224.

Chiplets 246 are unpatterned dies. Chiplets 246 can be provided by forming multiple layers on a substrate, as described below, and then dicing the substrate and the layers into chiplets 246. In one implementation, chiplets 246 can be formed from an InP wafer having a diameter of approximately one hundred millimeters (100 mm). In the present implementation, one of chiplets 246 is bonded to each IC 226. In other implementations, more or fewer chiplets 246 can be bonded to each IC 226.

In one implementation, chiplets 246 are group III-V chiplets. As used herein, the phrase “group III-V” refers to a compound semiconductor including at least one group III element, such as indium (In), gallium (Ga), aluminum (Al), and boron (B), and at least one group V element, such as arsenic (As), phosphorus (P), and nitrogen (N). By way of example, a group III-V semiconductor may take the form of indium phosphide (InP). “Group III-V” can also refer to a compound semiconductor that includes an alloy of a group III element and/or an alloy of a group V element, such as indium gallium arsenide (In_{X}Ga_{1-X}As), indium gallium nitride (In_{X}Ga_{1-X}N), aluminum gallium nitride (Al_{X}Ga_{1-X}N), aluminum indium gallium nitride (Al_{X}In_{Y}Ga_{1-X-Y}N), gallium arsenide phosphide nitride (GaAs_{A}P_{B}N_{1-A-B}), and aluminum indium gallium arsenide phosphide nitride (Al_{X}In_{Y}Ga_{1-X-Y}As_{A}P_{B}N_{1-A-B}), for example. “Group III-V” also refers generally to any polarity including but not limited to Ga-polar, N-polar, semi-polar, or non-polar crystal orientations. A group III-V material may also include either the Wurtzitic, Zincblende, or mixed polytypes, and may include single-crystal, monocrystalline, polycrystalline, or amorphous structures.

In various implementations, chiplets 246 can comprise lithium niobate (LiNbO₃), lithium tantalate (LiTa), potassium dihydrogen phosphate (KDP), deuterated potassium dihydrogen phosphate (DKDP), rubidium titanyl phosphate (RTP), potassium titanyl phosphate (KTP), potassium titanyl arsenate (KTA), barium borate (BBO), barium titanate (BTO), ammonium dihydrogen phosphate (ADP), cadmium telluride (CdTe), organic materials which demonstrate a strong Pockels effect, or any other suitable Pockels material.

FIG. 4B illustrates a cross-sectional view of a portion of a semiconductor structure corresponding to FIG. 4A processed in accordance with action 106 in flowchart 100A of FIG. 1A according to one implementation of the present application. The cross-sectional view in FIG. 4B generally corresponds to a portion of one of ICs 226 in FIG. 4A. As shown in FIG. 4B, in semiconductor structure 206B, chiplet 246 is bonded to substrate 224 in bonding window 244. Chiplet 246 includes bulk layer 248, etch stop layer 250, and active layers 252, 254, and 256.

Chiplet 246 can be formed by sequentially depositing etch stop layer 250 and active layers 252, 254, and 256 over bulk layer 248 used as a substrate. Chiplet 246 can be flipped relative to the orientation it was formed, such that bulk layer 248 is on the top and active layer 256 is on the bottom. Then chiplet 246 is bonded to substrate 224 in bonding window 244. Bulk layer 248 supports active layers 252, 254, and/or 256 during the bonding action. Chiplet 246 can be bonded using any suitable bonding technique. Where a device subsequently formed from active layers 252, 254, and/or 256 is configured to interact with device 232b, chiplet 246 can be bonded without using an adhesive that could interfere with such interaction. In one implementation, chiplet 246 is bonded in bonding window 244 using fusion bonding by contacting active layer 256 and dielectric 234, then applying heat and/or pressure. Chiplet 246 can be bonded to substrate 224 by oxygen plasma assisted direct bonding, whereby the surfaces of chiplet 246 and substrate 224 can be cleaned, then activated by an oxygen plasma, then placed in physical contact at room temperature to bond. In one implementation, after bonding, a low-temperature anneal can also be performed. For example, semiconductor structure 206B can be annealed at a temperature of approximately three hundred degrees Celsius (300° C.).

After the bonding action, chiplet 246 is situated in bonding window 244. Gap 258 is situated in bonding window 244 between chiplet 246 and sidewalls 237 and 243 of interlayer dielectrics 236 and 242. In semiconductor structure 206B, chiplet 246 is shown to overlie device 232b. In other implementations, chiplet 246 may overlie more or fewer devices of substrate 224. For example, devices 232b can be situated in an area of IC 226 (shown in FIG. 4A) that does not underlie chiplet 246.

Chiplet 246 represents an unpatterned die, suitable for patterning into a device. In one implementation, chiplet 246 is suitable or patterning into an optoelectronic device, such as a laser, a photodiode, or an electro-absorption modulator (EAM). For example, active layers 252 and 256 can function as a P type anode and an N type cathode, respectively, of a group III-V photodiode. In one implementation, the dopant types can be switched (i.e., N type doped active layer 252 and P type doped active layer 256). In other implementations, chiplet 246 can have other layering and/or doping suitable for other devices. Chiplet 246 may include more or fewer active layers than shown in FIG. 4B. In other implementations, some patterning may be performed prior to bonding.

In various implementations, bulk layer 248 can be an InP substrate having a thickness of approximately three microns (3 μm) to approximately forty microns (40 μm) or greater or less. In various implementations, etch stop layer 250 can comprise InGaAs having a thickness of approximately one hundred nanometers (100 nm) or greater or less. In one example, active layers 252, 254, and 256 form a P-I-N junction, and chiplet 246 is suitable for patterning into an optoelectronic device. In this example, active layer 252 can comprise InP implanted with boron or another appropriate P type dopant. In various implementations, active layer 252 has a thickness of approximately two microns (2 μm) or greater or less. As known in the art, active layer 252 can comprise a thin heavily doped contact layer near bulk layer 248 and a thick lightly doped cladding layer near active layer 254. In various implementations, active layer 252 can include other group III-V materials instead of or in addition to InP.

Continuing the above example, active layer 254 can comprise several undoped transitional layers, such as InGaAsP layers each having a thickness of approximately ten nanometers (10 nm). These transition layers can function as quantum wells to provide optical gain. As known in the art, active layer 254 can also comprise confinement layers around the quantum wells and having lower refractive index. In various implementations, active layer 254 has a combined thickness of approximately two hundred nanometers (200 nm) to approximately four hundred nanometers (400 nm) or greater or less. In various implementations, active layer 254 can include other group III-V materials instead of or in addition to InGaAsP.

Continuing the above example, active layer 256 can be a group III-V layer having an opposite doping type than active layer 252. Active layer 256 can comprises InP implanted with phosphorus or another appropriate N type dopant. In various implementations, active layer 256 has a thickness of approximately one hundred and fifty nanometers (150 nm) or greater or less. In various implementations, active layer 256 can include other group III-V materials instead of or in addition to InP.

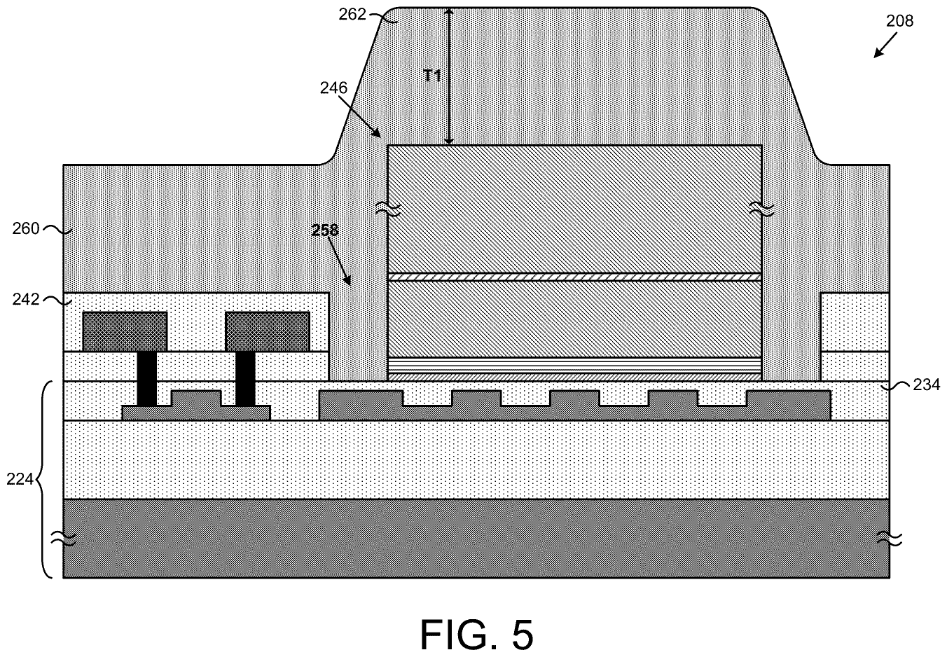

FIG. 5 illustrates a cross-sectional view of a portion of a semiconductor structure processed in accordance with action 108 in flowchart 100A of FIG. 1A according to one implementation of the present application. As shown in FIG. 5, in semiconductor structure 208, blanket dielectric 260 is formed over chiplet 246 and substrate 224.

In particular, blanket dielectric 260 is formed on interlayer dielectric 242, on dielectric 234 of substrate 224 in gap 258, and on chiplet 246. In various implementations, blanket dielectric 260 can comprise SiO₂, Si_{X}N_{Y}, or Si_{X}O_{Y}N_{Z}, or another dielectric. Blanket dielectric 260 can be formed, for example, by plasma enhanced chemical vapor deposition (PECVD) or high density plasma CVD (HDP-CVD).

Notably, although the exact topography of blanket dielectric layer 260 will depend on the formation process used, the topography of blanket dielectric 260 generally mirrors that of chiplet 246 and interlayer dielectric 242. In particular, blanket dielectric 260 includes portion 262 over chiplet 246 which protrudes. In various implementations, a deposition thickness T1 of blanket dielectric 260 can be approximately five microns (5 μm) to approximately eight microns (8 μm) or greater or less. In one implementation, in order to ensure that blanket dielectric 260 fills gap 258 without widened bonding window 244 more than necessary to align and bond chiplet 246, a thickness of chiplet 246 is kept less than or approximately equal to forty microns (40 μm).

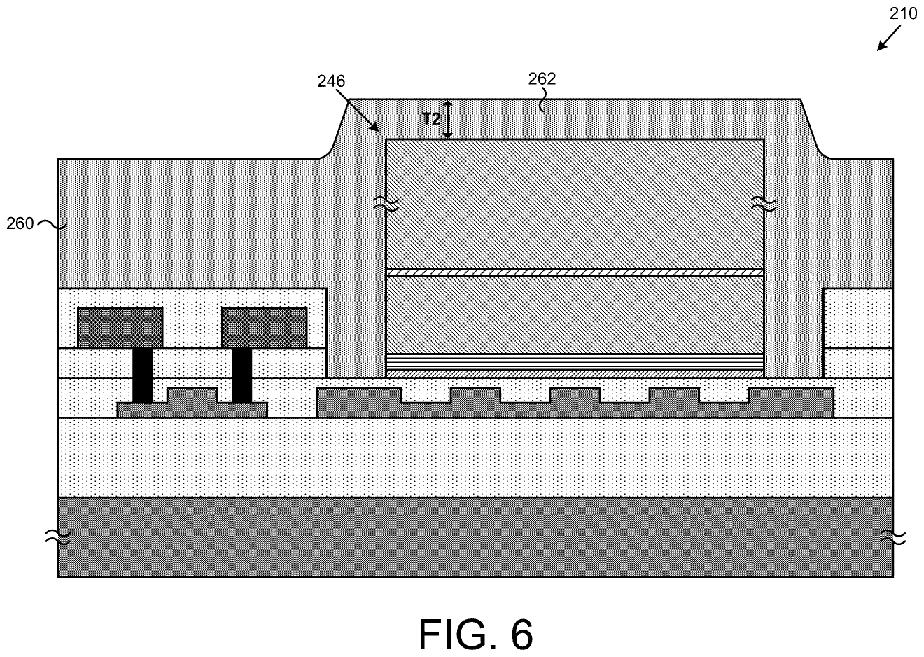

FIG. 6 illustrates a cross-sectional view of a portion of a semiconductor structure processed in accordance with action 110 in flowchart 100A of FIG. 1A according to one implementation of the present application. As shown in FIG. 6, in semiconductor structure 210, portion 262 of blanket dielectric 260 over chiplet 246 is thinned.

Portion 262 of blanket dielectric 260 can be thinned, for example, using CMP. After thinning, portion 262 will be significantly thinner than other portions of blanket dielectric 260. In various implementations, a thickness T2 of portion 262 after thinning can be approximately a half micron (0.5 μm) to approximately one and a half microns (1.5 μm) or greater or less.

FIG. 7 illustrates a cross-sectional view of a portion of a semiconductor structure processed in accordance with action 112 in flowchart 100B of FIG. 1B according to one implementation of the present application. As shown in FIG. 7, in semiconductor structure 212, blanket dielectric 260 is etched to expose bulk layer 248 without exposing active layers 252, 254, or 256.

Etching blanket dielectric 260 exposes top surface 264 and an upper portion of sidewall 266 of bulk layer 248. The remainder of chiplet 246, including a lower portion of bulk layer and all of etch stop layer 250 and active layers 252, 254, and 256 remain unexposed with blanket dielectric 260 thereon. In various implementations, a thickness T3 of sidewall 266 exposed after etching can be approximately one micron (1 μm) to approximately one and a half microns (1.5 μm) or greater or less. Blanket dielectric 260 can be etched, for example, using a blanket dry etch process. The etching action shown in FIG. 7 removes portion 262 (shown in FIG. 6) of blanket dielectric 260 which was over chiplet 246. Because bulk layer 248 is generally relatively thick, the etching action can easily remove the thinned thickness T2 of portion 262 and some thickness T3 from sidewall 266 while still having a large enough time window to be stopped before reaching active layers 252, 254, and 256.

As shown in FIG. 7, surface 268 of blanket dielectric 260 (the surface over interlayer dielectric 242) is at a higher level than the top surfaces of active layer 252 and etch stop layer 250. The thicknesses of interlayer dielectrics 236 and 242, blanket dielectric 260, etch stop layer 250, and active layers 252, 254, and 256, as well as the timings of the thinning action (shown in FIG. 6) and of the etching action (shown in FIG. 7), can be chosen such that surface 268 of blanket dielectric 260 is at a higher level than the top surface of top active layer 252 or the top surface of etch stop layer 250. FIG. 8 illustrates a cross-sectional view of a portion of a semiconductor structure processed in accordance with action 114 in flowchart 100B of FIG. 1B according to one implementation of the present application. As shown in FIG. 8, in semiconductor structure 214, bulk layer 248 of chiplet 246 (shown in FIG. 7) is removed.

Bulk layer 248 can be removed, for example, using a wet etch process. Etch stop layer 250 protects active layer 252 during the removal of bulk layer 248. Etch stop layer 250 can be configured as an etch stop for lower active layer 252. Etch stop layer along with blanket dielectric 260 encapsulates active layer 252, and when bulk layer 248 is removed by etching, etch stop layer 250 is a different material than bulk layer 248 that has significantly lower etch rate, such that the etching is selective to bulk layer 248. For example, where bulk layer 248 is InP and is removed by hydrochloric (HCl) wet etch, etch stop layer 250 can be InGaAs.

In the present implementation, after removing bulk layer 248, etch stop layer 250 can remain in semiconductor structure 214 as an active layer. For example, etch stop etch stop layer 250 can be an active group III-V layer, such as P type InGaAs, suitable for patterning into an optoelectronic device. In such implementation, the etching action shown in FIG. 7 should be designed so as not to expose etch stop layer 250. In other implementations, etch stop layer 250 can be a sacrificial layer removed after bulk layer 248.

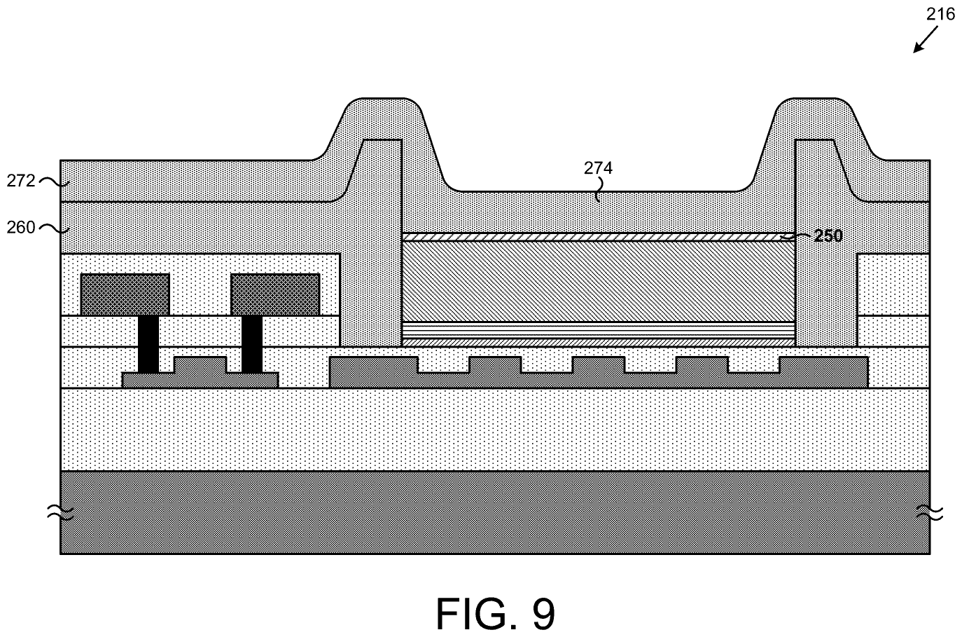

FIG. 9 illustrates a cross-sectional view of a portion of a semiconductor structure processed in accordance with action 116 in flowchart 100B of FIG. 1B according to one implementation of the present application. As shown in FIG. 9, in semiconductor structure 216, blanket dielectric 272 is formed over active layer 250 (where etch stop 250 is an active layer) and blanket dielectric 260.

In various implementations, blanket dielectric 272 can comprise SiO₂, Si_{X}N_{Y}, or Si_{X}O_{Y}N_{Z}, or another dielectric. Blanket dielectric 272 can be formed, for example, by PECVD or HDP-CVD. Notably, the topography of blanket dielectric 272 generally mirrors that of active layer 250 and blanket dielectric 260. In various implementations, a deposition thickness of blanket dielectric 272 can be approximately two microns (2 μm) or greater or less. Blanket dielectric 272 includes portion 274 over active layer 250 in a region where bulk layer 248 (shown in FIG. 7) was removed.

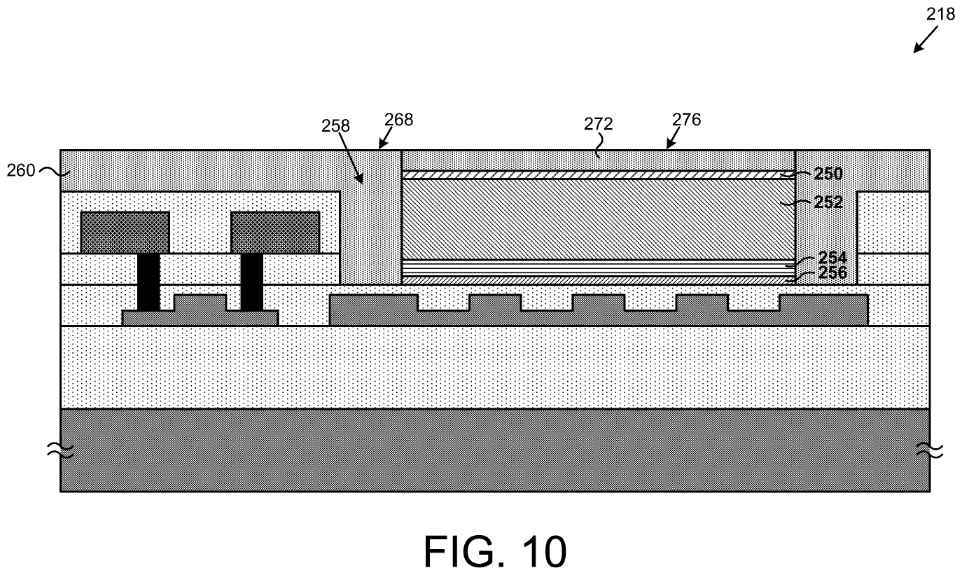

FIG. 10 illustrates a cross-sectional view of a portion of a semiconductor structure processed in accordance with action 118 in flowchart 100B of FIG. 1B according to one implementation of the present application. As shown in FIG. 10, in semiconductor structure 218, portion 274 (shown in FIG. 9) of blanket dielectric 272 over active layer 250 is planarized with blanket dielectric 260.

Portion 274 of blanket dielectric 272 over active layer 250 can be planarized with blanket dielectric 260, for example, using CMP. The planarizing action shown in FIG. 10 removes relatively large peaks of blanket dielectrics 262 and 272 that were over gap 258. After planarizing, top surfaces 268 and 276 of respective blanket dielectrics 260 and 272 are substantially planar and are at substantially the same level. As used herein, “substantially planar” refers to a surface being planar, except for normal dishing and other normal process variations associated with planarization. Likewise, “at substantially the same level” refers to two surfaces being level with each other, except for normal dishing and other normal process variations, such as minor interface discontinuities.

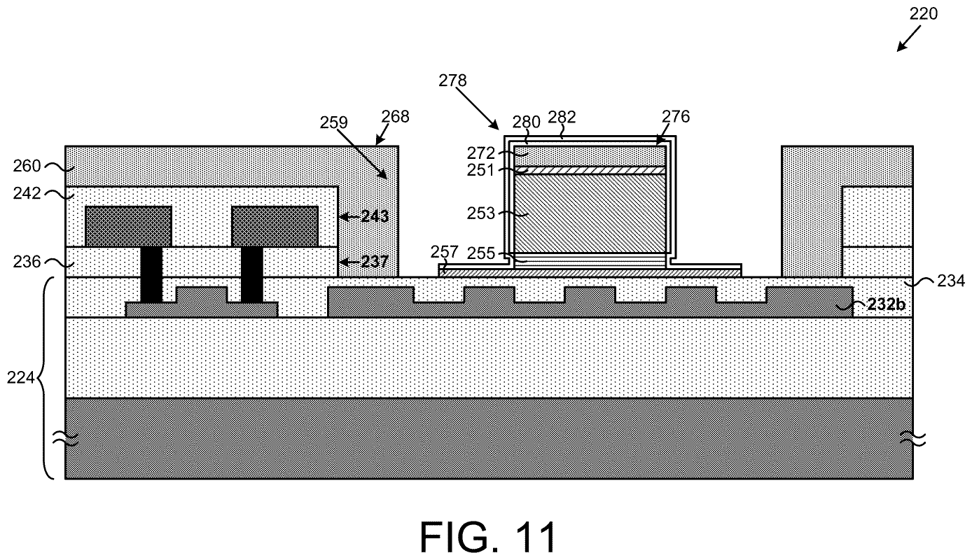

FIG. 11 illustrates a cross-sectional view of a portion of a semiconductor structure processed in accordance with action 120 in flowchart 100B of FIG. 1B according to one implementation of the present application. As shown in FIG. 11, in semiconductor structure 220, device 278 is formed from active layers 250, 252, 254, and 256 (shown in FIG. 10).

Device 278 can be formed from active layers 250, 252, 254, and 256 by patterning them into respective active layers 251, 253, 255, and 257. Device 278 can be formed by depositing and patterning a hardmask over blanket dielectric 272, then etching through blanket dielectric, through active layer 250, and into active layer 252 using an inductively coupled plasma (ICP) etch. Then active layer 252 can be etched through using a wet etch. In this implementation, active layer 252 may be selectively etched while active layer 254 performs as an etch stop. Then protective layer 280 can be formed on the top and an upper portion of the side of the structure. Then active layer 254 can be etched, for example, using a reactive ion etch (RIE) and/or a wet etch. Then protective layer 282 can be formed over the structure leaving a portion of active layer 256 exposed. Finally, active layer 256 can be etched through using a wet etch. In various implementations, protective layers 280 and 282 can comprise Si_{X}N_{Y} or Si_{X}O_{Y}N_{Z}.

Patterning active layers 251, 253, 255, and 257 extends the gap in the bonding window. That is, gap 259 (shown in FIG. 11) between device 278 and sidewalls 237 and 243 of interlayer dielectrics 236 and 242 is bigger than gap 258 (shown in FIG. 4B) between chiplet 246 and sidewalls 237 and 243. Blanket dielectric 260 is over interlayer dielectric 242, and in a portion of gap 259. Top surface 268 of blanket dielectric 260 is at a higher level than the top surfaces of active layers 251 and 253. Top surfaces 268 and 276 of respective blanket dielectrics 260 and 272 are substantially planar and are at substantially the same level, separated by a portion of gap 259.

In one implementation, device 278 is an optoelectronic device, such as a laser, a photodiode, or an EAM. For example, active layers 251 and/or 253 can function as a P type anode of a group III-V photodiode, and active layer 257 can function as an N type cathode of the group III-V photodiode. Device 278 is bonded to dielectric 234 of substrate 224. Device 278 is optically connected to device 232b in substrate 224. Device 278 is approximately aligned with device 232b. Device 278 is separated from device 232b by a thin portion of dielectric 234 that was used to protect devices 232a and 232b during bonding action 106 (shown in FIG. 4B). As described above, in various implementations, device 232b can be a waveguide, grating coupler, or an interferometer. In one implementation, device 232b may couple light to/from device 278 from/to another plane not visible in the cross-sectional view of FIG. 11. In another implementation, device 232b may couple light to/from patterned device 278 from/to a bottom of substrate 224. In various implementations, device 278 can be optically connected to additional devices (not shown in FIG. 11) in substrate 224. Similarly, devices 232a and 232b can be optically connected to additional devices (not shown in FIG. 11) in substrate 224 and/or to an optical input/output interface (not shown in FIG. 11).

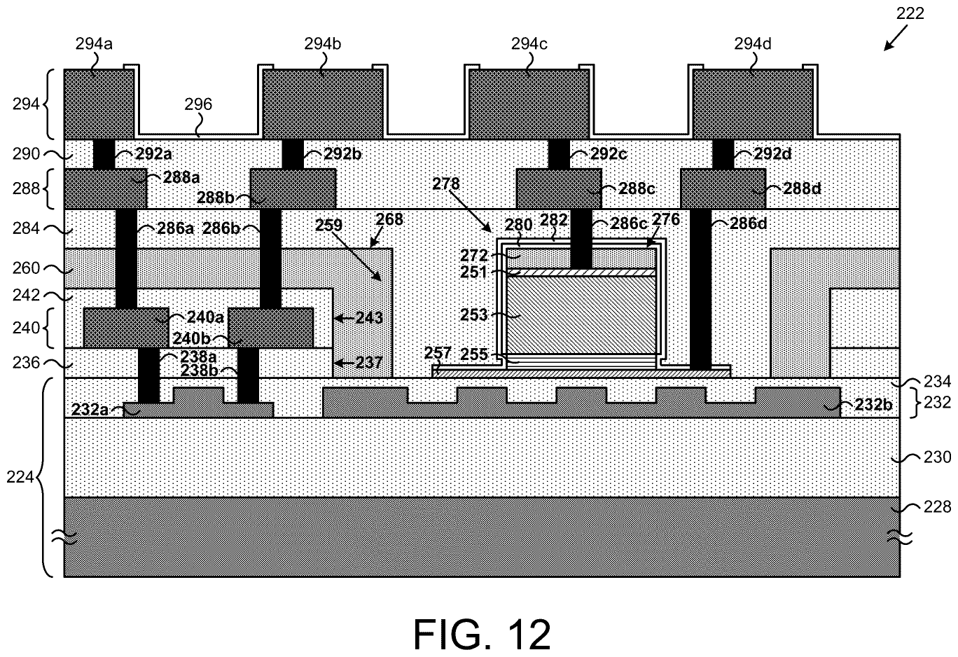

FIG. 12 illustrates a cross-sectional view of a portion of a semiconductor structure processed in accordance with action 122 in flowchart 100B of FIG. 1B according to one implementation of the present application. As shown in FIG. 12, in semiconductor structure 222, additional processing is completed. The additional processing includes forming interlayer dielectric 284, vias 286a and 286b, contacts 286c and 286d, interconnect metal layer 288, interconnect metal segments 288a, 288b, 288c, and 288d, interlayer dielectric 290, vias 292a, 292b, 292c, and 292d, interconnect metal layer 294, interconnect metal segments 294a, 294b, 294c, and 294d, and passivation layer 296.

Interlayer dielectric 284 is formed over blanket dielectric 260, in a portion of gap 259 over dielectric 234 and active layer 257, and over active layers 251, 253, and 255 of device 278. Interlayer dielectric 284 can be formed in a similar manner to interlayer dielectrics 236 and 242, as described above. Blanket dielectric 260 is under interlayer dielectric 284, and is between interlayer dielectric 284 and sidewalls 237 and 243.

Blanket dielectric 272 and protective layers 280 and 282 are under interlayer dielectric 284.

Vias 286a and 286b are situated in interlayer dielectric 284, blanket dielectric 260, and interlayers dielectric 242. Vias 286a and 286b connect interconnect metal segments 240a and 240b in interconnect metal layer 240 to interconnect metal segments 288a and 288b, respectively, in interconnect metal layer 288. Contact 286c is situated in interlayer dielectric 284, protective layers 280 and 282, and blanket dielectric 272. Contact 286d is situated in interlayer dielectric 284, and protective layer 282. Contacts 286c and 286d are connected to device 278 to apply or receive electricity. Contact 286c is connected to active layer 251. Contact 286d is connected to active layer 257. In one implementation, contacts 286c and 286d to device 278 can be formed concurrently with vias 286a and 286b to interconnect metal segments 240a and 240b.

Interconnect metal layer 288 is formed over interlayer dielectric 284. Interconnect metal layer 288 includes interconnect metal segments 288a, 288b, 288c, and 288d electrically coupled to vias and contacts 286a, 286b, 286c, and 286d respectively. Interconnect metal segments 288a, 288b, 288c, and 288d are situated in and under interlayer dielectric 290. Vias 292a, 292b, 292c, and 292d are situated in interlayer dielectric 290. Vias 292a, 292b, 292c, and 292d connect interconnect metal segments 288a, 288b, 288c, and 288d in interconnect metal layer 288 to interconnect metal segments 294a, 294b, 294c, and 294d, respectively, in interconnect metal layer 294. Interconnect metal layer 294 is formed over interlayer dielectric 290. Interconnect metal layer 294 includes interconnect metal segments 294a, 294b, 294c, and 294d electrically coupled to vias 292a, 292b, 292c, and 292d respectively. Vias 286a, 286b, 292a, 292b, 292c, and 292d, and contacts 286c and 286d can be formed in a similar manner to contacts 238a and 238b, as described above. Interconnect metal segments 288a, 288b, 288c, 288d, 294a, 294b, 294c, and 294d can be formed in a similar manner to interconnect metal segments 240a and 240b, as described above.

Passivation layer 296 is formed over and on sidewalls of interconnect metal segments 294a, 294b, 294c, and 294d, and over interlayer dielectric 290. Passivation layer 290 can be formed by conformal deposition, for example, by physical vapor deposition (PVD) or CVD techniques. In various implementations, passivation layer 296 can include a semiconductor-based dielectric such as Si_{X}O_{Y}, Si_{X}N_{Y}, or Si_{X}O_{Y}N_{Z}. In various implementations, passivation layer 296 can have a thickness of approximately fifty angstroms (50 Å) to approximately two hundred angstroms (200 Å). In various implementations, passivation layer 296 comprises multiple passivation layers. As shown in FIG. 12, windows are formed in passivation layer 296 exposing portions of interconnect metal segments 294a, 294b, 294c, and 294d. Thus, the exposed portions of interconnect metal segments 294a, 294b, 294c, and 294d can function as bond pads for electrical connections external to semiconductor structure 222.

Contacts 238a and 238b, vias 286a, 286b, 292a, and 292b, and interconnect metal segments 240a, 240b, 288a, 288b, 294a, and 294b together route electricity to/from device 232a, which can be, for example, a silicon Mach-Zehnder modulator. Similarly, contacts 286c and 286d, vias 292c and 292d, and interconnect metal segments 288c, 288d, 294c, and 294d together route electricity to/from device 278, which can be, for example, a group III-V photodiode. In various implementations, some contacts, vias, and interconnect metal segment may route to other components in semiconductor structure 222 instead of or in addition to bond pads at interconnect metal layer 294.

It is noted that, although device 278 is formed by patterning chiplet 246 in the present implementation, as shown across FIGS. 10 and 11, in other implementations, such patterning may be omitted. For example, referring to FIG. 10, chiplet 246 may already have appropriate dimensions to perform as an optoelectronic device.

Referring to FIG. 3, it is also noted that, although bonding window 244 is formed in both interlayer dielectrics 236 and 242 after forming contacts 238a and 238b and interconnect metal segments 240a and 240b in the present implementation, other implementations are possible. Namely, device 278 can generally be formed at any level in semiconductor structure 222 in FIG. 12. For example, bonding window 244 in FIG. 3 can be formed in only interlayer dielectric 224 while interlayer 236 is intact, and chiplet 246 can be bonded and processed before even forming contacts 238a and 238b or interconnect metal segments 240a and 240b. In such implementation, contacts to device 278 may be formed substantially concurrently with contacts to device 232a.

Fabricating semiconductor structures according to the present invention results in several advantages. First, since portion 262 of blanket dielectric 260 is thinned (as shown in FIG. 6) prior to etching blanket dielectric 260 (as shown in FIG. 7), the entire top surface 264 of bulk layer 248, as well as an upper portion of sidewall 266 of bulk layer 248, are exposed. This enables bulk layer 248 to be removed in a single action (as shown in FIG. 8). In contrast, conventional techniques tend to leave residual bulk portions when removing the main portion of a bulk layer. The residual bulk portions require more complex design considerations. More actions are needed to completely remove the bulk layer, increasing fabrication time and cost. Further, forming a device such as device 278 can require starting with a wider chiplet in order to account for the volumes that will form residual bulk portions. The present invention can utilize a narrower chiplet 246, and accordingly, a narrower bonding window 244, allowing more area in IC 226 for other structures.

Second, active layers 252, 254, and 256 are not damaged during the removal of bulk layer 248 (shown in FIG. 8), since active layers 252, 254, and 256 were not exposed by the etching action (shown in FIG. 7). Rather active layers 252, 254, and 256 encapsulated by blanket dielectric 260 on their sides and etch stop layer 250 on the top. Conventional techniques can fail to properly protect active layers during removal of bulk layers, due to poor encapsulation of the active layers and/or due to the protective layers not withstanding the harsh additional actions needed to completely remove the bulk layers. Damage to active layers negatively impacts the performance of a device formed from such active layers. The present invention exhibits improved device performance due to improved protection of active layers 252, 254, and 256.

Third, surface 268 of blanket dielectric 260 being at a higher level than the top surface of the top active layer (etch stop layer 250 or active layer 252), as shown in FIGS. 7 and 8, helps ensure that, even if blanket dielectric 272 shown in FIG. 9 is formed relatively thin, the top surface (268+276) of semiconductor structure 218 shown in FIG. 10 is still substantially planar across the whole wafer, and does not have significant contouring between inner areas over bonding window 244 and outer areas over interlayer dielectric 242.

Fourth, because top surfaces 268 and 276 of respective blanket dielectrics 262 and 272 are substantially planar and are at substantially the same level (as shown in FIG. 10) immediately prior forming device 278 (as shown in FIG. 11), forming device 278 is significantly easier. Planar topologies can be processed with more commonly available fabrication technologies, and generally facilitate better alignment during lithography, allowing for smaller devices less prone to fabrication errors.

Thus, various implementations of the present application achieve improved fabrication of semiconductor structures using bonded chiplets and novel combinations to overcome the deficiencies in the art. From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A method comprising:
providing a substrate;
bonding a chiplet to said substrate, said chiplet comprising a bulk layer and an active layer;
forming a first blanket dielectric over said chiplet and said substrate;
thinning a first portion of said first blanket dielectric over said chiplet;
etching said first blanket dielectric to expose said bulk layer without exposing said active layer;
removing said bulk layer.

2. The method of claim 1, wherein said active layer comprises indium phosphide (InP).

3. The method of claim 1, wherein said substrate comprises a semiconductor-on-insulator (SOI) substrate.

4. The method of claim 1, further comprising:
forming a second blanket dielectric over said active layer and said first blanket dielectric;
planarizing a second portion of said second blanket dielectric over said active layer with said first blanket dielectric.

5. The method of claim 1, further comprising forming a first device from said active layer.

6. The method of claim 5, wherein said first device is a laser, a photodiode, or an electro-absorption modulator (EAM).

7. The method of claim 5, wherein said first device is optically connected to a second device in said substrate.

8. The method of claim 1, wherein said thinning is performed by chemical mechanical polishing (CMP).

9. The method of claim 1, wherein said etching exposes a sidewall of said bulk layer.

10. The method of claim 1, wherein said chiplet further comprises an etch stop layer to protect said active layer during said removing said bulk layer.

11. A method comprising:
providing a group IV substrate;
bonding a group III-V chiplet to said substrate, said group III-V chiplet comprising a bulk group III-V layer and an active group III-V layer;
forming a first blanket dielectric over said group III-V chiplet and said group IV substrate;
thinning a portion of said first blanket dielectric over said group III-V chiplet;
etching said first blanket dielectric to expose said bulk group III-V layer without exposing said active group III-V layer;
removing said bulk group III-V layer.

12. The method of claim 11, wherein said active group III-V layer comprises indium phosphide (InP), and said group IV substrate comprises a silicon-on-insulator substrate.

13. The method of claim 11, further comprising:
forming a second blanket dielectric over said active group III-V layer and said first blanket dielectric;
planarizing a second portion of said second blanket dielectric over said active group III-V layer with said first blanket dielectric.

14. A structure comprising:
a substrate;
a first interlayer dielectric over said substrate;
a bonding window in said first interlayer dielectric;
an optoelectronic device in said bonding window and bonded to said substrate;
a gap in said bonding window between said optoelectronic device and a sidewall of said first interlayer dielectric;
a first blanket dielectric in said gap and over said first interlayer dielectric, said first blanket dielectric having a first substantially planar top surface situated higher than a top active layer of said optoelectronic device;
a second interlayer dielectric in said gap and over said first blanket dielectric and said top active layer.

15. The structure of claim 14, wherein said optoelectronic device comprises indium phosphide (InP).

16. The structure of claim 14, further comprising a second blanket dielectric over said top active layer, under said second interlayer dielectric, and having a second substantially planar top surface at substantially the same height as said first substantially planar top surface.

17. The structure of claim 14, wherein said substrate comprises a semiconductor-on-insulator (SOI) substrate.

18. The structure of claim 14, wherein said optoelectronic device is optically connected to a second device in said substrate.

19. The structure of claim 14, wherein said top active layer is configured as an etch stop for a lower active layer of said optoelectronic device.

20. The structure of claim 14, further comprising a contact metal in said second interlayer dielectric and connected to said optoelectronic device.
